(19) United States
(12) Patent Application Publication
(10) Pub. No.: US 2007/0120179 A1
(43) Pub. Date: May 31, 2007

(54) SONOS type non-volatile memory devices having a laminate blocking insulation layer and methods of manufacturing the same

(76) Inventors: Hong-Bae Park, Seoul (KR); Yu-Gyun Shin, Gyeonggi-do (KR)

Correspondence Address: MYERS BIGEL SIBLEY & SAJOVEC, PO BOX 37428, RALEIGH, NC, 27627, US

(21) Appl. No.: 11/505,033

(22) Filed: Aug. 16, 2006

(30) Foreign Application Priority Data
Aug. 19, 2005 (KR) 10-2005-0076131

(51) Int. Cl. H01L 29/792; H01L 21/336

(52) U.S. Cl. 257/324; 257/E29.309; 438/288; 257/E21.423

(57) ABSTRACT

A SONOS type non-volatile memory device includes a substrate having source/drain regions doped with impurities and a channel region between the source/drain regions. A tunnel insulation layer including silicon oxide is formed on the channel region of the substrate. A charge-trapping insulation layer including silicon nitride is formed on the tunnel insulation layer. A blocking insulation layer is formed on the charge-trapping insulation layer. The blocking insulation layer has a laminate layered structure in which a plurality of layers, at least one of which includes a metal oxide layer, are sequentially stacked. An electrode is formed on the blocking insulation layer.

### CROSS-REFERENCE TO RELATED APPLICATION

This application claims priority under 35 USC §119 to Korean Patent Application No. 10-2005-76131, filed on Aug. 19, 2005, the contents of which are herein incorporated by reference in its entirety for all purposes.

### FIELD OF THE INVENTION

The present invention relates to non-volatile memory devices and methods of manufacturing the memory devices. More particularly, the present invention relates to SONOS type non-volatile memory devices and methods of manufacturing the memory devices.

### BACKGROUND OF THE INVENTION

Non-volatile memory devices may be classified into two general categories depending upon the structure of their unit cells, namely: floating gate type non-volatile memory devices; and floating trap type non-volatile memory devices. A floating trap type non-volatile memory device includes a silicon-oxide-nitride-oxide semiconductor (SONOS) type non-volatile memory device.

A unit cell of the floating gate type non-volatile memory device includes a tunnel oxide layer, a floating gate electrode, a dielectric layer and a control gate electrode sequentially formed on a semiconductor substrate. Charges are stored as free carriers in the floating gate electrode to program the floating gate type non-volatile memory device with data. In contrast, the charges are extracted from the floating gate electrode to erase the data from the floating gate type non-volatile memory device. When defects are generated in the tunnel oxide layer between the floating gate electrode and the semiconductor substrate, the charges in the floating gate electrode can be lost from the floating gate type non-volatile memory device. To avoid/prevent loss of charges, the tunnel oxide layer may be formed to have a relatively large thickness. However, a thick tunnel oxide layer can necessitate the use of high operational voltages, which may complicate the structure of associated peripheral circuits and may limit the integration density of floating gate type non-volatile memory devices.

A unit cell of the SONOS type non-volatile memory device includes a tunnel insulation layer including silicon oxide, a charge-trapping insulation layer including silicon nitride, a blocking insulation layer including silicon oxide and an electrode including a conductive material, which are sequentially formed on a semiconductor substrate. To program the SONOS type non-volatile memory device with data, electrons are stored in a charge trap of the charge-trapping insulation layer between the electrode and the semiconductor substrate. To erase the data from the SONOS type non-volatile memory device, the electrons are extracted from the charge trap of the charge-trapping insulation layer. The tunnel insulation layer may be relatively thin because the electrons are stored in the charge-trapping insulation layer within a deep-level charge trap. The thin tunnel insulation layer may allow the SONOS type non-volatile memory device to operate with a relatively low operational voltage, and may simplify the structure of the associated peripheral circuits. As a result, SONOS type non-volatile memory devices may be more easily manufactured with a higher integration density than floating gate type non-volatile memory devices. An example of a SONOS type non-volatile memory device is disclosed in U.S. Pat. No. 6,501,681, which is incorporated herein by reference.

In an attempt to obtain higher integration densities of SONOS type non-volatile memory devices, the thickness of the blocking insulation layer can be reduced. However, as the blocking insulation layer becomes sufficiently thin, a leakage current through the blocking insulation layer can increase and reduce the operational characteristics of the memory device.

A metal oxide layer may be used for the blocking insulation layer of the SONOS type non-volatile memory device. The metal oxide layer may reduce the leakage current through a thin equivalent oxide thickness (EOT). An example of a SONOS type non-volatile memory device that uses a metal oxide layer as a blocking insulation layer is disclosed in Korean Patent No. 456580, which is incorporated herein by reference.

Although a metal oxide layer may be used for the blocking insulation layer to allow higher integration densities with SONOS type non-volatile memory devices, it can be desirable to provide yet higher integration densities and electrical characteristics for these memory devices.

### SUMMARY OF EMBODIMENTS OF THE INVENTION

Some embodiments of the present invention are directed to a SONOS type non-volatile memory device and related methods of manufacturing such devices that may allow increased integration density and/or which may have improved electrical characteristics.

In some embodiments of the present invention, a SONOS type non-volatile memory device includes a substrate having source/drain regions doped with impurities, and a channel region between the source/drain regions. A tunnel insulation layer including silicon oxide is formed on the channel region of the substrate. A charge-trapping insulation layer including silicon nitride is formed on the tunnel insulation layer. A blocking insulation layer is formed on the charge-trapping insulation layer. The blocking insulation layer has a laminate layered structure in which a plurality of layers, at least one of which includes a metal oxide layer, are sequentially stacked. An electrode including a conductive material is formed on the blocking insulation layer.

In some further embodiments, at least one of the plurality of layers of the blocking insulation layer includes a silicon oxide layer. The blocking insulation layer may include a plurality of alternating layers of metal oxide and silicon oxide stacked upon one another.

In some further embodiments, the charge-trapping insulation layer may have a laminate layered structure in which a plurality of charge-trapping insulation sub-layers are stacked.

In some further embodiments, the blocking insulation layer may be formed by a chemical vapor deposition (CVD) process and/or an atomic layer deposition (ALD) process.

In some other embodiments of the present invention, a method of manufacturing a SONOS type non-volatile memory device includes forming a first thin layer including silicon oxide on a substrate. A second layer including silicon nitride is formed on the first thin layer. A third thin layer is then formed on the second thin layer. The third thin layer includes a laminate layered structure in which a plurality of layers, at least one of which includes a metal oxide layer, are sequentially stacked. A fourth thin layer including a conductive material is formed on the third thin layer. The fourth, third, second and first thin layers are etched to form an electrode, a blocking insulation layer, a charge-trapping insulation layer, and a tunnel insulation layer, respectively, as a gate structure on the substrate. Impurities are implanted into the substrate adjacent to both sides of the gate structure to form source/drain regions and a channel region between the source/drain regions.

According to some further embodiments, formation of the third thin layer may include forming a plurality of alternating layers of metal oxide and silicon oxide stacked upon one another. The third thin layer may be formed by a CVD process and/or an ALD process.

According to some further embodiments, the blocking insulation layer may be formed from a laminate layered structure by stacking a plurality of layers, at least one of which includes metal oxide, on one another. The blocking insulation layer with the laminate layered structure including metal oxide may have a sufficiently high crystallizing temperature so that the temperature used when forming the gate structure may not unacceptably deteriorate the characteristics of the blocking insulation layer. The blocking insulation layer may be formed so as to have a relatively thin EOT and/or a reduced leakage current through the blocking insulation layer. Relatedly, the integration density of the SONOS type non-volatile memory device may be improved.

### BRIEF DESCRIPTION OF THE DRAWINGS

The above and other features and advantages of the invention will become readily apparent by reference to the following detailed description when considered in conjunction with the accompanying drawings wherein:

FIG. 1 is a cross-sectional view illustrating a SONOS type non-volatile memory device in accordance with some embodiments of the present invention;

FIGS. 2A to 2E are cross-sectional views illustrating methods of manufacturing the SONOS type non-volatile memory device in FIG. 1 in accordance with some embodiments of the present invention;

FIG. 3 is an enlarged cross-sectional view illustrating a third layer in FIG. 2C in accordance with some embodiments of the present invention;

FIG. 4 is a graph illustrating exemplary capacitances of the blocking insulation layer in FIG. 1; and

FIG. 5 is a graph illustrating exemplary leakage currents of the blocking insulation layer in FIG. 1.

### DESCRIPTION OF EMBODIMENTS OF THE INVENTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the terms “and/or” and “/” include any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

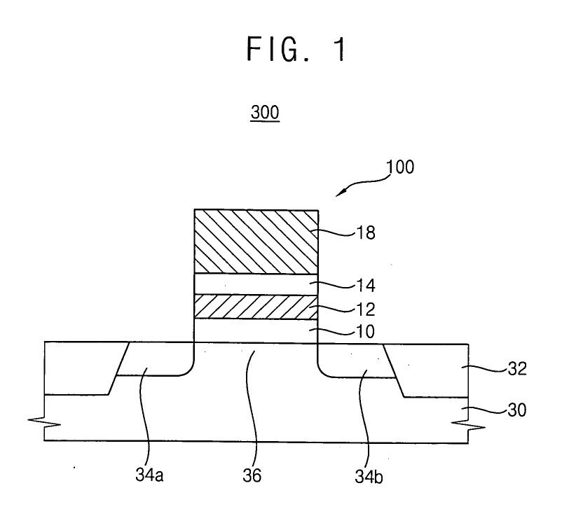

FIG. 1 is a cross-sectional view illustrating a SONOS type non-volatile memory device in accordance with some embodiments of the present invention.

Referring to FIG. 1, a SONOS type non-volatile memory device 300 includes a semiconductor substrate 30 and a gate structure 100 as a unit cell formed on the semiconductor substrate 30.

Examples of the semiconductor substrate 30 include a silicon substrate, a silicon-on-insulator (SOI) substrate, a germanium substrate, a germanium-on-insulator (GOI) substrate, a silicon-germanium substrate, an epitaxial substrate obtained by a selective epitaxial growth (SEG) process, etc. In a present exemplary embodiment, a silicon substrate is used for the semiconductor substrate 30. Alternatively, when the SONOS type non-volatile memory device 300 has a stacked structure, an epitaxial substrate obtained by the SEG process may be used for the semiconductor substrate 30.

Isolation layers 32 are formed in the semiconductor substrate 30 to define an active region and a field region of the semiconductor substrate 30. Examples of the isolation layers 32 include a field oxide layer, a trench isolation layer, etc. A trench isolation layer may be preferable for use as the isolation layers 32 because it may allow higher integration density compared to a field isolation layer.

Source/drain regions 34a and 34b doped with impurities are formed in the semiconductor substrate 30. The source/drain regions 34a and 34b are formed in the semiconductor substrate 30 adjacent to sides of the gate structure 100. Impurities may be implanted into the semiconductor substrate 30 adjacent to sides of the gate structure 100 to form the source/drain regions 34a and 34b.

A channel region 36 may be formed in the semiconductor substrate 30 between the source/drain regions 34a and 34b. The gate structure 100 is formed on the channel region 36 of the semiconductor substrate 30.

The gate structure 100 includes a tunnel insulation layer 10, a charge-trapping insulation layer 12, a blocking insulation layer 14 and an electrode 18. The tunnel insulation layer 10 serves as an energy barrier to electron tunneling therethrough. The tunnel insulation layer 10 may include silicon oxide, and may be formed by a thermal oxidation process.

The charge-trapping insulation layer 12 stores electrons. In some embodiments, the charge-trapping insulation layer 12 includes silicon nitride. The charge-trapping insulation layer 12 may further include metal oxynitride, silicon oxynitride, and/or silicon nitride. The charge-trapping insulation layer 12 can include a laminate layered structure in which a plurality of charge-trapping insulation sub-layers are stacked, and which may include a metal oxynitride layer, a silicon oxynitride layer, and/or a silicon nitride layer. In some embodiments, the charge-trapping insulation layer 12 has a laminate layered structure that includes a silicon nitride/hafnium oxynitride/silicon oxynitride layer, a silicon nitride/hafnium silicon oxynitride/hafnium oxynitride layer, a hafnium oxynitride/silicon nitride layer, a silicon nitride/hafnium oxynitride/aluminum oxynitride layer, a silicon nitride/hafnium aluminum oxynitride/hafnium oxynitride layer, a silicon nitride/hafnium aluminum oxynitride/aluminum oxynitride layer, a silicon nitride/zirconium oxynitride layer, and/or a zirconium silicon oxynitride/silicon nitride layer. For example, the charge-trapping insulation layer 12 may have a laminate layered structure that includes stacked layers that include a silicon nitride layer and a hafnium oxynitride layer, a silicon nitride layer and a silicon oxynitride layer, a silicon nitride layer and a hafnium silicon oxynitride layer, a silicon nitride layer and an aluminum oxynitride layer, a silicon nitride layer and a hafnium aluminum oxynitride layer, a silicon nitride layer and a hafnium aluminum oxynitride layer, a silicon nitride layer and a zirconium oxynitride layer, and/or a zirconium silicon oxynitride layer and a silicon nitride layer.

The blocking insulation layer 14 prevents charge migration therethrough when a voltage is applied to the electrode 18. The blocking insulation layer 14 can have a laminate structure in which at least one metal oxide layer is repeatedly stacked therein. The blocking insulation layer 14 may include a silicon oxide layer and a metal oxide layer stacked on one another.

Exemplary embodiments of the blocking insulation layer 14 with a laminate structure include a hafnium oxide/silicon oxide layer, a hafnium silicon oxide/silicon oxide layer, a zirconium oxide/silicon oxide layer, a zirconium silicon oxide/silicon oxide layer, an aluminum oxide/silicon oxide layer, and/or an aluminum silicon oxide/silicon oxide layer.

Further exemplary embodiments of the blocking insulation layer 14 with a laminate structure include different combinations of metal oxide layers and a silicon oxide layer that are alternately stacked upon one another. For example, the blocking insulation layer 14 can include a hafnium oxide/aluminum oxide layer, a zirconium oxide/hafnium oxide layer, a zirconium oxide/aluminum oxide layer, and/or a hafnium oxide/aluminum oxide/silicon oxide layer.

When the blocking insulation layer 14 has a laminate structure with an EOT above about 70 Å, the SONOS type non-volatile memory device 300 may have an unacceptably limited integration density. In contrast, when the blocking insulation layer 14 has a laminate structure has an EOT below about 5 Å, the associated manufacturing processes to stack the associated thin layers may be unacceptably complex because of variability of the process steps. Accordingly, it may be advantageous to provide the blocking insulation layer 14 with a laminate structure having an EOT in a range between about 5 Å to about 70 Å. The blocking insulation layer 14 may be formed by, for example, the CVD process and/or the ALD process. In the exemplary embodiment, because the ALD process can provide higher integration density, the blocking insulation layer 14 is formed by the ALD process.

The electrode 18 is formed on the blocking insulation layer 14 from a conductive material, and a voltage can be applied to the electrode 18. Example conductive materials from which the electrode 18 may be formed can include polysilicon and/or a metal having a work function below about 4.0 eV.

As describe above, the gate structure 100 of the SONOS type non-volatile memory device 300 may include the tunnel insulation layer 10 including silicon oxide, the charge-trapping insulation layer 12 including silicon nitride, the blocking insulation layer 14 having the laminate layered structure, and the electrode 18. By forming the blocking insulation layer 14 with a laminate layered structure of a plurality of stacked layers, at least one of which comprises a metal oxide layer, the blocking insulation layer 14 may have a higher crystallizing temperature and a relatively thin EOT, and/or it may have a lower leakage current through the blocking insulation layer 14.

Operations will now be explained that may be carried out to program and erase data in the SONOS type non-volatile memory device 300.

Programming the SONOS type non-volatile memory device 300 with data includes grounding the semiconductor substrate 30. A positive voltage is applied to the electrode 18 to create an electric field between the semiconductor substrate 30 and the gate structure 100 in a first direction, and thereby generating a Fowler-Nordheim current traversing the tunnel insulation layer 10. Electrons in the channel region 36 between the source/drain regions 34a and 34b overcome an energy barrier of the tunnel insulation layer 10 and flow therethrough into the charge-trapping insulation layer 12. An energy barrier of the blocking insulation layer 14 blocks movement of the electrons from the charge-trapping insulation layer 12 to the electrode 18. As a result, the electrons are trapped in the charge-trapping insulation layer 12 and the SONOS type non-volatile memory device 300 becomes programmed to store the data.

Erasing the data from the SONOS type non-volatile memory device 300 includes grounding the semiconductor substrate 30. A negative voltage is applied to the electrode 18 to create an electric field between the semiconductor substrate 300 and the gate structure 100 in a second direction substantially opposite to the first direction, thereby generating a Fowler-Nordheim current traversing the tunnel insulation layer 10 in a direction substantially opposite to that of the Fowler-Nordheim current generated when programming the device 300 with the data. The electrons in the charge-trapping insulation layer 12 overcome the energy barrier of the tunnel insulation layer 10 so that the electrons flow therethrough into the semiconductor substrate 30, thereby erasing the data from the SONOS type non-volatile memory device 300.

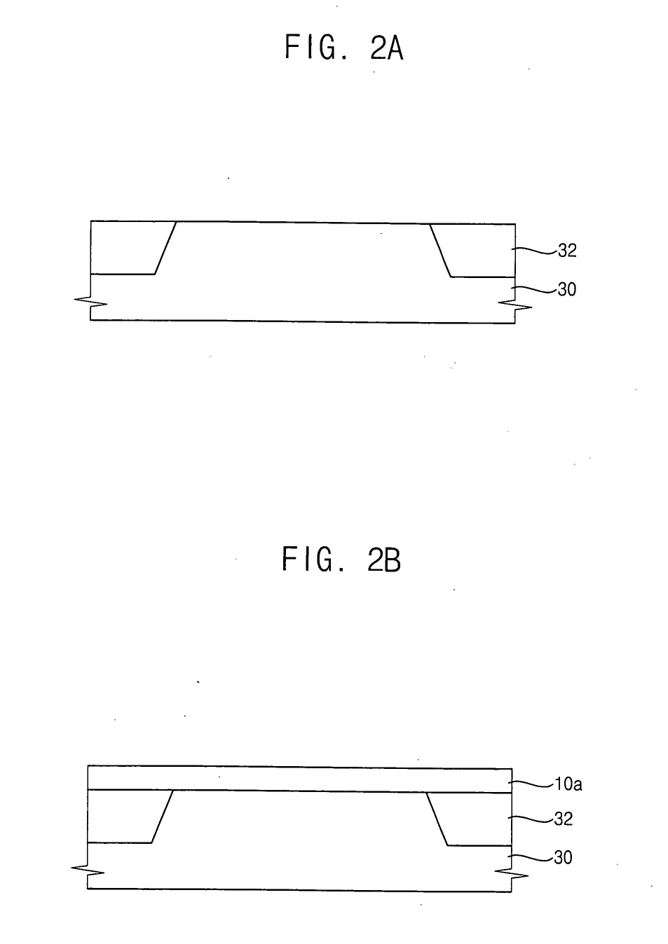

FIGS. 2A to 2E are cross-sectional views illustrating methods of manufacturing the SONOS type non-volatile memory device in FIG. 1 according to some embodiments of the present invention.

Referring to FIG. 2A, trench isolation layers 32 are formed in the semiconductor substrate 30 to define an active region and a field region of the semiconductor substrate 30. Using trench isolation layers as the isolation layers 32 may allow higher density device fabrication compared to use of a field isolation layers as the isolation layers 32.

The isolation layers 32 may be formed by sequentially forming a pad oxide layer (not shown) and a pad nitride layer (not shown) on the semiconductor substrate 30. The pad oxide layer and the pad nitride layer are patterned to form a pad oxide layer pattern and a pad nitride layer pattern partially exposing a surface of the semiconductor substrate 30. The semiconductor substrate 30 is etched using the pad oxide layer pattern and the pad nitride layer pattern as an etching mask to form a trench at a surface portion of the semiconductor substrate 30. The semiconductor substrate 30 is thermally treated to cure damage of the semiconductor substrate 30 generated by forming the trench. An oxide layer (not shown) having good gap-filling characteristics is formed on the semiconductor substrate 30 to fill up the trench. The oxide layer may be formed by a plasma-enhanced chemical vapor deposition (PECVD) process. The oxide layer is removed by a chemical mechanical polishing (CMP) process to expose a surface of the pad nitride layer pattern. The pad nitride layer pattern and the pad oxide layer pattern are then removed by an etching process using a phosphorous acid solution. As a result, the oxide layer may only exist in the trench so as to complete the trench isolation layers 102.

Referring to FIG. 2B, a first thin layer 10a including silicon oxide is formed on the semiconductor substrate 30 and the isolation layers 32. The first thin layer 10a can be converted into the tunnel oxide layer 10 in FIG. 1 by a thermal oxidation process such as described below.

A thermal oxidation process to form the first thin layer 10a may be carried out at a temperature in a range between about 900° C. to about 1,200° C. To reduce and/or prevent an unacceptable temperature-induced alteration of the semiconductor substrate 30 from the thermal oxidation process, the thermal oxidation process may be performed with the temperature being gradually increased from a low temperature to the high temperature in the range between about 900° C. to about 1,200° C. After forming the first thin layer 10a at the temperature of about 900° C. to about 1,200° C., the temperature can be gradually decreased. Exemplary reaction materials that may be used in the thermal oxidation process of the semiconductor substrate 30 can include oxygen (O₂) and/or water vapor (H₂O).

Because electrons are stored in the trap of the charge-trapping insulation layer 12 to program the SONOS type non-volatile memory device 300 with the data, the first thin layer 10a can be relatively thin. In some embodiments, the first thin layer 10a may have a thickness in a range between about 20 Å to about 50 Å, or more preferably between about 20 Å to about 40 Å, or even more preferably between about 25 Å to about 35 Å, or still more preferably may have a thickness of about 30 Å.

Referring to FIG. 2C, a second thin layer 12a including silicon nitride is formed on the first thin layer 10a, which can also include silicon oxide. The second thin layer 12a can be configured as the charge-trapping insulation layer 12 in FIG. 1 by the following exemplary process. The second thin layer 12a including the silicon nitride may be formed by a CVD process. The CVD process may include a low-pressure CVD (LPCVD) process and/or a PECVD process.

The LPCVD process to form the second thin layer 12a may be carried out using a SiH₂Cl₂ gas and a 4NH₂ gas as reaction gases at a temperature in a range between about 700° C. to about 800° C. The PECVD process to form the second thin layer 12a may be carried out using a SiH₄ gas and a NH₃ gas as a reaction gas at a temperature in a range between about 250° C. to about 350° C. In this example embodiment, the second thin layer 12a may have a thickness in a range between about 50 Å to about 150 Å, or more preferably between 50 Å to about 120 Å, or even more preferably between 80 Å to about 100 Å, or still more preferably may have a thickness of about 90 Å.

The second thin layer 12a may include additional or layers other than silicon nitride. For example, the second thin layer 12a may include silicon oxynitride, metal oxynitride, and/or silicon nitride. The second thin layer 12a may have a laminate structure in which a thin layer including silicon nitride is repeatedly stacked. Furthermore, after forming a silicon oxide layer and a metal oxide layer, the silicon oxide layer and the metal oxide layer may be nitrified to form the silicon oxynitride layer and the metal oxynitride layer. The nitridation process may be performed using a N₂ gas, a NO gas, an O₂ gas, and/or a NH₃ gas at a temperature in a range between about 650° C. to about 1,050° C.

A third thin layer 14a may be formed on the second thin layer 12a. The third thin layer 14a can have a laminate structure in which at least one metal oxide layer is repeatedly stacked therein. The third thin layer 14a may be converted into the blocking insulation layer 14 in FIG. 1 by the following process. The third thin layer 14a may be formed by an ALD process and/or a CVD process. The third thin layer 14a may have a thickness in a range between about 5 Å to about 70 Å.

The laminate structure of the third thin layer 14a may include a repeatedly stacked hafnium oxide/silicon oxide layer. A process for forming the repeatedly stacked hafnium oxide/silicon oxide layer will now be described.

A chamber is provided with a temperature in a range between about 200° C. to about 500° and a pressure in a range between about 0.3 Torr to about 3.0 Torr. The semiconductor substrate 30 with the second thin layer 12a is loaded into the chamber. A reaction material including a metal precursor, for example, a hafnium precursor such as TEMAH (tetrakis ethyl methyl amino hafnium, Hf[NC₂H₅CH₃]₄) is applied to the second thin layer 12a for a time between about 0.5 seconds to about 3 seconds. Thus, a first portion of the reaction material is chemisorbed on the second thin layer 12a. A second portion of the reaction material excluding for the first portion is physisorbed on the second thin layer 12a or drifts in the chamber. A purge gas such as an argon gas is introduced into the chamber for a time between about 0.5 seconds to about 20 seconds to remove the second portion of the reaction material. As a result, hafnium precursor molecules corresponding to the chemisorbed first portion of the reaction material remain on the second thin layer 12a. An oxidizing agent is introduced into the chamber for a time between about 1 second to about 7 seconds. The hafnium precursor molecules corresponding to the chemisorbed first portion of the reaction material are chemically reacted with the oxidizing agent to oxidize the hafnium precursor molecules. A purge gas is introduced into the chamber to remove the oxidizing agent non-reacted with the hafnium precursor molecules, and thereby forming a solid material including hafnium oxide on the second thin layer 12a. A cycle including applying the reaction material, introducing the purge gas, introducing the oxidizing agent and introducing the purge gas is repeated at least once more to form a hafnium oxide layer on the second thin layer 12a.

Processes substantially the same as those for forming the hafnium oxide layer, except for using a silicon precursor in place of the hafnium precursor, are carried out on the hafnium oxide layer to form a silicon oxide layer on the hafnium oxide layer.

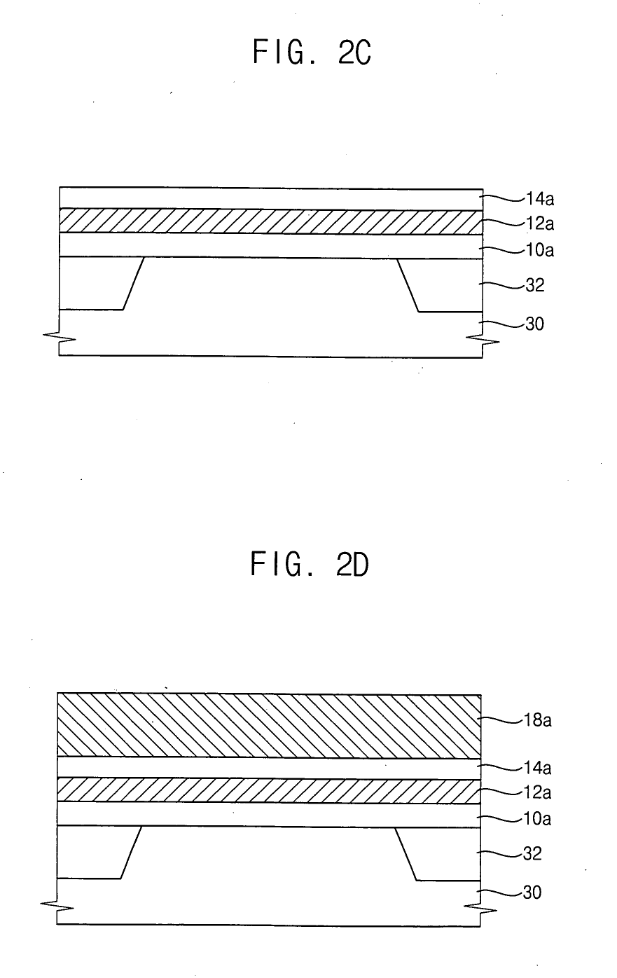

As shown in FIG. 3, the processes for forming the hafnium oxide layer and for forming the silicon oxide layer are repeated to form the third thin layer 14a having the laminate structure in which the hafnium oxide layer 140a and the silicon oxide layer 140b are repeatedly stacked on the second thin layer 12a.

In the illustrated exemplary embodiment, the fabrication process has formed the third thin layer 14a with a laminate structure in which the metal oxide layer and the silicon oxide layer have been alternately stacked on one another.

In some other embodiments, the third thin layer 14a may have a laminate structure in which different metal layers are repeatedly stacked on one another, or a laminate structure in which different metal oxide layers and a silicon oxide layer are alternately stacked on one another.

Referring to FIG. 2D, a fourth thin layer 18a is formed on the third thin layer 14a. The fourth thin layer 18a may be converted into the electrode 18 of the gate structure 100 in FIG. 1 by the following process. The fourth thin layer 18a may include polysilicon and/or metal having a work function of no less than 4.0 eV.

When the third thin layer 14a has a laminate structure, it may have a high crystallizing temperature. Thus, although the fourth thin layer 18a may be formed at a slightly higher temperature, the higher crystallizing temperature of the third thin layer 14a may allow the fourth thin layer 18a to be formed without undesirable effect on the characteristics on the third thin layer 14a.

Referring to FIG. 2E, the first thin layer 10a, the second thin layer 12a, the third thin layer 14a and the fourth thin layer 18a are patterned to respectively form the tunnel insulation layer 10, the charge-trapping insulation layer 12, the blocking insulation layer 14 and the electrode 18 of the gate structure 100 in FIG. 1 on the semiconductor substrate 30.

A photoresist pattern 80 partially exposing the fourth thin layer 18a is formed on the fourth thin layer 18a. The first thin layer 10a, the second thin layer 12a, the third thin layer 14a and the fourth thin layer 18a are etched using the photoresist pattern 80 to form the gate structure 100 on the semiconductor substrate 30.

Impurities are implanted into the semiconductor substrate 30 adjacent to both sides of the gate structure 100 using the photoresist pattern 80 as an ion implantation mask to form source/drain regions 34a and 34b. The impurities implanted into the semiconductor substrate 30 include phosphorous, arsenic, etc. These can be used alone or in a combination thereof. As a result, a channel region 36 is formed between the source/drain regions 34a and 34b (FIG. 1).

The photoresist pattern 80 is then removed from the electrode 18 to provide the SONOS type non-volatile memory device 300 that includes the gate structure having the tunnel insulation layer 10, the charge-trapping insulation layer 12, the blocking insulation layer 14 and the electrode 18 as the unit cell in FIG. 3.

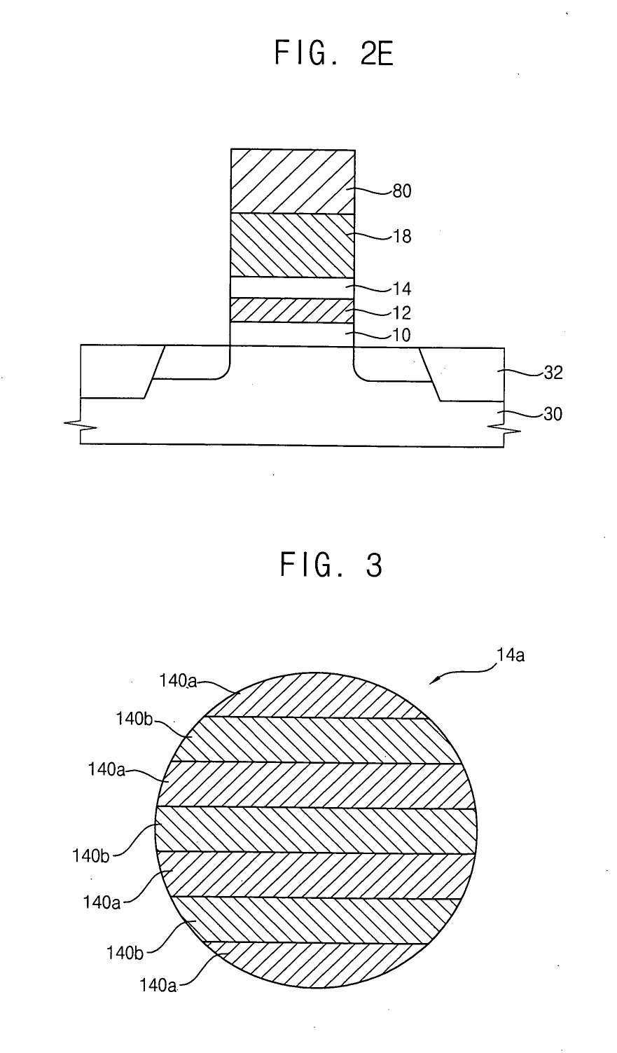

FIG. 4 is a graph illustrating exemplary capacitances of the blocking insulation layer 14 in FIG. 1 and a conventional blocking insulating layer. In FIG. 4, a curved line -●- represents a capacitance of the blocking insulation layer 14 having a laminate structure in which a hafnium oxide layer and a silicon oxide layer are stacked repeatedly on one another as shown in FIG. 2C in accordance with some embodiments of the present invention. A curved line -▪- indicates a capacitance of a conventional blocking insulation layer of silicon oxide. As shown in FIG. 4, the blocking insulation layer 14 formed in accordance with some embodiments of the present invention may have substantially the same capacitance as a conventional blocking insulating layer of silicon oxide, as illustrated by lines -●- and -▪-.

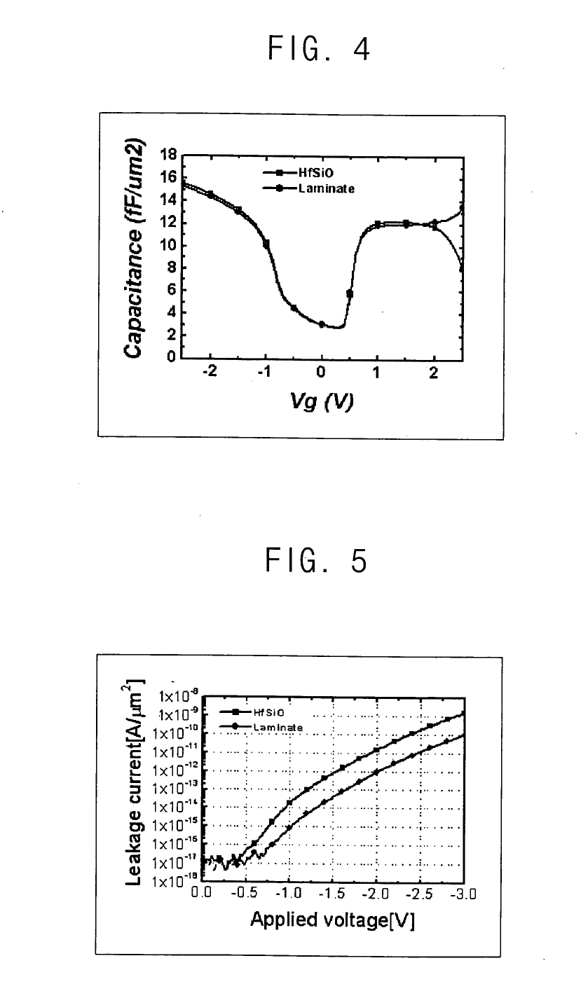

FIG. 5 is a graph illustrating exemplary leakage currents of the blocking insulation layer 14 in FIG. 1 and a conventional blocking insulating layer. In FIG. 5, a curved line -●- represents a leakage current of the blocking insulation layer 14 having a laminate structure in which a hafnium oxide layer and a silicon oxide layer are stacked repeatedly on one another as shown in FIG. 2C in accordance with some embodiments of the present invention. A curved line -▪- indicates a leakage current of a conventional blocking insulation layer of silicon oxide. As shown in FIG. 5, the leakage current of the blocking insulation layer 14 formed in accordance with some embodiments of the present invention may be substantially lower than the leakage current of a conventional blocking insulating layer of silicon oxide, as illustrated by lines -●- and -▪-.

A SONOS type non-volatile memory device may advantageously be formed with a blocking insulating layer having a laminate structure, such as a stacked structure of a metal oxide, and which may be formed as a thin layer with a low leakage current.

Moreover, in some embodiments of the present invention, the SONOS type non-volatile memory device may have a thin EOT. A leakage current through the blocking insulation layer may be sufficiently reduced so that the SONOS type non-volatile memory device may have improved electrical characteristics and/or may allow a higher integration density.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A SONOS type non-volatile memory device comprising:
a substrate;
source/drain regions in the substrate and doped with impurities;
a channel region in the substrate between the source/drain regions;
a tunnel insulation layer including silicon oxide on the channel region;
a charge-trapping insulation layer including silicon nitride on the tunnel insulation layer opposite the channel region;
a blocking insulation layer on the charge-trapping insulation layer opposite the tunnel insulation layer, the blocking insulation layer having a laminate layered structure in which a plurality of layers, at least one of which includes a metal oxide layer, are sequentially stacked; and
an electrode including a conductive material formed on the blocking insulation layer opposite the charge-trapping insulation layer.

2. The SONOS type non-volatile memory device of claim 1, wherein the charge-trapping insulation layer further comprises metal oxynitride and/or silicon oxynitride.

3. The SONOS type non-volatile memory device of claim 2, wherein the charge-trapping insulation layer has a laminate layered structure in which a plurality of charge-trapping insulation sub-layers are stacked.

4. The SONOS type non-volatile memory device of claim 1, wherein at least one of the plurality of layers of the blocking insulation layer comprises a silicon oxide layer.

5. The SONOS type non-volatile memory device of claim 4, wherein the blocking insulation layer comprises a plurality of alternating layers of metal oxide and silicon oxide stacked upon one another.

6. The SONOS type non-volatile memory device of claim 1, wherein the blocking insulation layer is formed by a CVD process and/or an ALD process.

7. The SONOS type non-volatile memory device of claim 1, wherein the at least one metal oxide layer of the blocking insulation layer comprises hafnium, zirconium, and/or aluminum.

8. The SONOS type non-volatile memory device of claim 1, wherein the blocking insulation layer has a thickness in a range between about 5 Å to about 70 Å.

9. The SONOS type non-volatile memory device of claim 1, wherein the conductive material of the electrode comprises polysilicon and/or a metal having a work function of no less than about 4.0 eV.

10. A method of manufacturing a SONOS type non-volatile memory device, comprising:
forming a first thin layer including silicon oxide on a substrate;
forming a second thin layer including silicon nitride on the first thin layer;
forming a third thin layer on the second thin layer, the third thin layer having a laminate layered structure in which a plurality of layers, at least one of which includes a metal oxide layer, are sequentially stacked;
forming a fourth thin layer including a conductive material on the third thin layer;
etching the first, second, third and fourth thin layers to form a tunnel insulation layer, a charge-trapping insulation layer, a blocking insulation layer, and an electrode, respectively, as a gate structure on the substrate; and
implanting impurities into the substrate adjacent to both sides of the gate structure to form source/drain regions.

11. The method of claim 10, wherein the second thin layer is formed from metal oxynitride and/or silicon oxynitride.

12. The method of claim 11, wherein the second thin layer is formed as a laminate layered structure by stacking a plurality of charge-trapping insulation sub-layers on one another.

13. The method of claim 11, wherein forming the second thin layer including the metal oxynitride comprises:
forming a metal oxide layer on the first thin layer; and
nitrifying the metal oxide layer.

14. The method of claim 11, wherein forming the second thin layer including the silicon oxynitride comprises:
forming a silicon oxide layer on the first thin layer; and
nitrifying the silicon oxide layer.

15. The method of claim 10, wherein at least one of the plurality of layers of the third thin layer comprises a silicon oxide layer.

16. The method of claim 15, wherein formation of the third thin layer comprises forming a plurality of alternating layers of metal oxide and silicon oxide stacked upon one another.

17. The method of claim 10, wherein the third thin layer is formed by a CVD process and/or an ALD process.

18. The method of claim 10, wherein the metal oxide layer of the third thin layer is formed from a material comprising hafnium, zirconium, and/or aluminum.

19. The method of claim 10, wherein the third thin layer is formed to have a thickness in a range between about 5 Å to about 70 Å.

20. The method of claim 10, wherein the fourth thin layer is formed from a conductive material that comprises polysilicon and/or a metal having a work function of no less than about 4.0 eV.
